(19) United States
(12) Patent Application Publication
(10) Pub. No.: US 2019/0210879 A1
(43) Pub. Date: Jul. 11, 2019

(54) ELECTRICAL CONTACT, CONNECTOR, AND METHOD FOR PRODUCING ELECTRICAL CONTACT

(71) Applicants: Yazaki Corporation, Tokyo (JP); NATIONAL INSTITUTE OF ADVANCED INDUSTRIAL SCIENCE AND TECHNOLOGY, Tokyo (JP)

(72) Inventors: Kikuo MORI, Shizuoka (JP); Tetsuo SHIMIZU, Ibaraki (JP)

(73) Assignees: Yazaki Corporation, Tokyo (JP); NATIONAL INSTITUTE OF ADVANCED INDUSTRIAL SCIENCE AND TECHNOLOGY, Tokyo (JP)

(21) Appl. No.: 16/356,104

(22) Filed: Mar. 18, 2019

Related U.S. Application Data
(63) Continuation of application No. PCT/JP2017/033721, filed on Sep. 19, 2017.

(30) Foreign Application Priority Data
Sep. 21, 2016 (JP) 2016-184601
Sep. 14, 2017 (JP) 2017-176627

(51) Int. Cl. C01B 32/182; H01H 1/04; H01R 13/03; C23C 16/04; C23C 16/455

(52) U.S. Cl. CPC C01B 32/182; H01H 1/04; C23C 16/455; C23C 16/04; H01R 13/03

(57) ABSTRACT

A method for producing an electrical contact includes a step of preparing an electrical contact material including a layer that contains a carbon material on a base material that contains a metallic material having resistivity of 1.59×10⁻⁸ Ωm to 9.00×10⁻⁷ Ωm; and a step of processing the electrical contact material obtained to produce an electrical contact, wherein the carbon material is a graphene monolayer or a graphene laminate in which a plurality of the graphene monolayers is laminated, the step of preparing an electrical contact material includes a step of laminating a carbon material layer in which the layer that contains the carbon material is laminated on the base material by microwave surface-wave plasma CVD method or thermal CVD method, and the step of laminating a carbon material layer includes supplying a mixed gas including a source gas that contains carbon and hydrogen gas.

### CROSS-REFERENCE TO RELATED APPLICATION(S)

This application is a continuation application of International Application PCT/JP2017/033721, filed on Sep. 19, 2017, and designating the U.S., the entire contents of which are incorporated herein by reference.

### BACKGROUND OF THE INVENTION

### 1. Field of the Invention

The present invention relates to an electrical contact, a connector, and a method for producing an electrical contact.

### 2. Description of the Related Art

In automobiles, wire harnesses are required to have high contact reliability so that complicated systems function safely. Furthermore, with reduction in size and weight, connectors for wire harnesses of automobiles are required to achieve an improvement in contact reliability based on a conduction mechanism.

However, it is often the case that a contact surface in an electrical contact of a connector is formed of a metal such as copper or a copper alloy or formed by a plated layer of tin or a tin alloy provided on the metal. In these cases, when an oxide film of copper is generated on the contact surface, this oxide film hinders conduction, leading to reduction in contact reliability. In an electrical contact on which an oxide film is generated, it is necessary to apply a high contact force to the electrical contact so as to break the oxide film and bring metal surfaces into contact with each other.

Reduction in contact reliability due to this oxide film is a problem not only for electrical contacts in connectors for wire harnesses of automobiles but also for electrical contacts provided in devices such as connectors, switches, and relays which are configured to open and close electric circuits and are used for various electrical equipment.

To solve this problem, the following technique is known. That is, a plated layer of a noble metal is formed on the contact surface to prevent generation of an oxide film. For example, Japanese Patent Application Laid-open No. 2011-204651 discloses a terminal geometry of an electrical contact provided with a substrate, a composite material layer provided on the substrate, and a gold film or a gold alloy film that covers at least a part of the composite material layer. In the composite material layer, a carbon polymer-based material serving as a reinforcement material is dispersed in a base material that includes gold or a gold alloy.

However, since noble metals are expensive, forming a plated layer of a noble metal increases the production cost of electrical contacts.

### SUMMARY OF THE INVENTION

The present invention has been made in light of the situation, and an object of the present invention is to provide an electrical contact which has high contact reliability and enables reduction in production cost.

A method for producing an electrical contact according to one aspect of the present invention includes a step of preparing an electrical contact material including a layer that contains a carbon material on a base material that contains a metallic material having resistivity of 1.59×10⁻⁸ Ωm or more and 9.00×10⁻⁷ Ωm or less; and a step of processing the electrical contact material obtained to produce an electrical contact, wherein the carbon material is a graphene monolayer or a graphene laminate in which a plurality of the graphene monolayers is laminated, the step of preparing an electrical contact material includes a step of laminating a carbon material layer in which the layer that contains the carbon material is laminated on the base material by microwave surface-wave plasma CVD method or thermal CVD method, and the step of laminating a carbon material layer includes supplying a mixed gas including a source gas that contains carbon and hydrogen gas.

According to another aspect of the present invention, in the method for producing an electrical contact, it is preferable that the step of preparing an electrical contact material further comprises a step of conducting a pretreatment in which a surface of the base material is cleaned with pretreatment gas plasma containing an inert gas and hydrogen gas, and the step of laminating a carbon material layer is a step of laminating the layer that contains the carbon material on the base material pretreated by the step of conducting a pretreatment.

According to still another aspect of the present invention, in the method for producing an electrical contact, it is preferable that the step of laminating a carbon material layer includes heating the base material and supplying the mixed gas.

According to still another aspect of the present invention, in the method for producing an electrical contact, it is preferable that the step of laminating a carbon material layer includes heating the base material at a temperature of 300° C. to 400° C. and supplying the mixed gas.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic view of a surface-wave plasma CVD apparatus;

FIG. 2 is an optical microscopic image of a copper foil of Production Example 1 that includes a layer including a graphene monolayer;

FIG. 3 illustrates a load resistance of the copper foil of Production Example 1 that includes the layer including the graphene monolayer;

FIG. 4 illustrates a load resistance after oxidation of the copper foil of Production Example 1 that includes the layer including the graphene monolayer;

FIG. 5 is an optical microscopic image of a copper foil of Comparative Production Example 1;

FIG. 6 illustrates a load resistance of the copper foil of Comparative Production Example 1;

FIG. 7 illustrates a load resistance after oxidation of the copper foil of Comparative Production Example 1;

FIG. 8 illustrates an external appearance of a copper substrate of Production Example 2 that includes a layer including a graphene monolayer;

FIG. 9 is an optical microscopic image of the copper substrate of Production Example 2 that includes the layer including the graphene monolayer;

FIG. 10 illustrates a Raman spectrum of the copper substrate of Production Example 2 that includes the layer including the graphene monolayer;

FIG. 11 illustrates an external appearance of a nickel substrate of Production Example 3 that includes a layer including a graphene laminate;

FIG. 12 is an optical microscopic image of the nickel substrate of Production Example 3 that includes the layer including the graphene laminate;

FIG. 13 illustrates a Raman spectrum of the nickel substrate of Production Example 3 that includes the layer including the graphene laminate; and

FIG. 14 illustrates a load resistance of the nickel substrate of Production Example 3 that includes the layer including the graphene laminate.

### DETAILED DESCRIPTION OF THE PREFERRED EMBODIMENTS

### Electrical Contact Material

An electrical contact material employed in an embodiment of the present invention includes a layer that contains a carbon material on a base material that contains a metallic material. In this specification, a layer that contains a carbon material is also referred to as “carbon material layer”.

### Base Material

The base material contains a metallic material having resistivity of 1.59×10⁻⁸ Ωm or more and 9.00×10⁻⁷ Ωm or less. A metallic material having resistivity within the above range is preferable for being used as an electrical contact. The resistivity herein is a value at 20° C.

The metallic material is not particularly limited as long as it has resistivity within the above range. Examples of the metallic material include silver (resistivity: 1.59×10⁻⁸ Ωm), copper (resistivity: 1.68×10⁻⁸ Ωm), gold (resistivity: 2.21×10⁻⁸ Ωm), aluminum (resistivity: 2.65−10⁻⁸ Ωm), nickel (resistivity: 6.99×10⁻⁸ Ωm), tin (resistivity: 1.09×10⁻⁸ Ωm), and alloys thereof.

The alloy may include two or more kinds of metallic elements M1 selected from the group consisting of silver, copper, gold, aluminum, nickel and tin, or may include one or more kinds of the metallic elements M1 and one or more kinds of metallic element M2 other than the metallic elements M1. These examples of the alloy may further contain a non-metallic element. The alloy typically contains 50 mass % or more of the metallic elements M1 in total in the alloy.

Specific examples of the alloy include a copper alloy, more specifically, an alloy of copper and zinc stipulated in, for example, JIS C2600 and JIS 2700 (resistivity is typically 5×10⁻⁸ Ωm or more and 7×10⁻⁸ Ωm or less), and an alloy of copper and tin stipulated in, for example, JIS C1020 and JIS 1100.

As the metallic material, stainless steel such as austenitic stainless steel (for example, SUS304 and SUS316) is also preferably used. The resistivity of each exemplified alloy is typically within the aforementioned range.

Among these examples, copper, a copper alloy, aluminum, an aluminum alloy, and stainless steel are preferable, and copper and a copper alloy are more preferable from the viewpoint of being used as connectors for wire harnesses.

The shape and size of the base material are not particularly limited as long as a desired electrical contact is prepared from the base material. The base material has a thickness of, for example, 0.15 mm or more and 3.0 mm or less.

### Carbon Material Layer

In the electrical contact material, the carbon material layer is provided on the base material. Accordingly, using the electrical contact material in the preparation of an electrical contact makes it possible to prevent generation of a metallic oxide film on the base material. Therefore, the electrical contact according to the present invention has excellent contact reliability without hindering conduction. In addition, the electrical contact according to the present invention is produced at low cost as compared with an electrical contact in the related art that prevents generation of a metallic oxide film by a plated layer of a noble metal. Furthermore, since the electrical contact according to the present invention employs the electrical contact material including the carbon material layer on the base material, it is possible to achieve low friction.

The carbon material contained in the layer that contains the carbon material is a graphene monolayer or a graphene laminate in which a plurality of graphene monolayers is laminated.

The graphene monolayer is a sheet-shaped material having a planar hexagonal lattice structure including sp2-bonded carbon atoms.

The graphene laminate is a laminate in which a plurality of graphene monolayers (that is, two or more layers) is laminated. In this specification, the graphene laminate also includes graphite formed by laminating the plurality of graphene monolayers.

The carbon material layer has a thickness of is 0.335 nm or more. Note that the lower limit of the thickness corresponds to a thickness of one carbon atom in a graphene monolayer.

It is preferable that the carbon material layer should have a thickness of 0.335 nm or more and 1.0 mm or less from the aspect of excellent electrical conductivity and contact reliability as an electrical contact. The carbon material layer having such a thickness includes a graphene monolayer, a graphene laminate including two laminated graphene monolayers, or a graphene laminate including a large number of graphene monolayers (generally referred to as “graphite”).

In a case where the carbon material layer is a graphene monolayer, the thickness of the carbon material layer is measured by an atomic force microscope (AFM). In a case where the carbon material layer is a multi-layer and is thick, the thickness is measured by a laser profilometer. Even when a plurality of graphene monolayers is laminated, if the number of laminated layers (thickness) is small, the thickness of the carbon material layer is measured by an atomic force microscope (AFM).

Measuring a Raman spectroscopy spectrum, it is possible to determine whether a layer including a graphene monolayer is formed on the base material, or whether a layer including a laminate in which generally two or more graphene monolayers are laminated (for example, a laminate generally called as “multilayer graphene”) is formed on the base material.

Specifically, when a G band (around 1585 cm⁻¹) and a 2D band (around 2700 cm⁻¹) are observed in the Raman spectroscopy spectrum, the carbon material contained in the layer on the base material is identified as a graphene monolayer or the aforementioned laminate. Furthermore, based on the position and shape of the 2D band and the intensity ratio of the 2D band to the G band, it is possible to determine whether the carbon material contained in the layer on the base material is a graphene monolayer or, if the carbon material is a laminate, it is possible to determine how many graphene monolayers are laminated therein (see A. C. Ferrari, J. C. Meyer, V. Scardaci, C. Casiraghi, M. Lazzeri, F. Mauri, S. Piscanec, D. Jiang, K. S. Novoselov, S. Roth and A. K. Geim, Phys Rev. Lett. 97, 187401 (2006), A. C, Ferrari, Solid State Commun. 143, 47 (2007), and L. M. Malard, M. A. Pimenta, G. Dresselhaus and M. S. Dresselhaus, Phys. Rep. 473, 51 (2009)). More specifically, comparison of a relationship between the peak values of the G band and the 2D band makes it possible to determine the number of laminated graphene on the base material. Typically, when the peak value of the G band<the peak value of the 2D band, the carbon material is determined as a graphene layer, and when the peak value of the G band=the peak value of the 2D band, the carbon material is determined to include two layers, and when the peak value of the G band>the peak value of the 2D band, the carbon material is determined to include three or more layers.

The carbon material layer may contain other substances in addition to the carbon material within a range where generation of a metallic oxide film is prevented.

However, it is preferable that the carbon material layer should not contain metallic particles. The carbon material layer containing no metallic particles is highly effective in preventing generation of an oxide film and has excellent conductivity and contact reliability as an electrical contact. Furthermore, it is more preferable that the carbon material layer should include only the carbon material. Such a carbon material layer is more highly effective in preventing generation of an oxide film and has more excellent conductivity and contact reliability as an electrical contact.

In the electrical contact material, an intermediate layer such as a plated layer may be provided between the base material and the carbon material layer.

A material for forming the intermediate layer is not particularly limited as long as it is generally used for an electrical contact. Examples of the material include nickel, cobalt, copper, tin, and alloys thereof (for example, an alloy of tin and lead). Furthermore, a plurality of intermediate layers may be laminated. The intermediate layer typically has a thickness of 0.01 μm or more and 10 μm or less.

However, it is preferable that the carbon material layer should be directly laminated on the base material. When preparing an electrical contact, such an electrical contact material is highly effective in preventing generation of an oxide film and has excellent conductivity and contact reliability.

The electrical contact material employed in the present invention is not particularly limited in shape and may have any shape as long as it is preferable as a shape of a raw material for obtaining a desired electrical contact. Specific examples of the shape of the electrical contact material include a foil, a plate, a rod, a wire, a tube, a thread, and a deformed thread.

The carbon material layer does not necessarily cover the entire surface of the base material, and the carbon material layer may be present continuously or discontinuously on the base material.

### Electrical Contact and Connector

The electrical contact according to the present invention is prepared using the electrical contact material. In other words, the electrical contact according to the present invention includes the electrical contact material.

It is preferable that at least a part of the contact surface (surface used for conduction) of the electrical contact should be covered with the carbon material layer. This configuration prevents generation of an oxide film and enhances contact reliability.

However, it is preferable that the entire contact surface should be covered with the carbon material layer. This configuration further prevents generation of an oxide film and further enhances contact reliability.

The shape of the electrical contact is not particularly limited and may be determined appropriately depending on the intended use.

The electrical contact according to the present invention employs the electrical contact material including the carbon material layer on the base material, which enhances contact reliability. Accordingly, even though the electrical contact has an intricate shape, it is possible to obtain the above effects.

The electrical contact is preferably used not only for connectors for wire harnesses of automobiles but also for connectors for various kinds of electrical equipment. In other words, a connector according to the present invention includes the electrical contact. In addition to connectors, the electrical contact is preferably used for devices such as switches and relays which are configured to open and close electric circuits. In connectors for wire harnesses of automobiles, a connector used in an engine room is more likely to be exposed to volatile gas or the like at high temperatures. Even when used as a connector in an engine room, the electrical contact according to the present invention prevents generation of an oxide film and enhances contact reliability.

### Method for Producing Electrical Contact

A method for producing an electrical contact according to the present invention includes a step of preparing an electrical contact material including a layer that contains a carbon material on a base material that contains a metallic material having resistivity of 1.59×10⁻⁸ Ωm or more and 9.00×10⁻⁷ Ωm or less; and a step of processing the electrical contact material obtained to produce an electrical contact. The carbon material is a graphene monolayer or a graphene laminate in which a plurality of the graphene monolayers is laminated.

Specifically, the preparation of an electrical contact material involves lamination of a carbon material layer in which the layer that contains the carbon material is laminated on the base material that contains the metallic material having resistivity of 1.59×10⁻⁸ Ωm or more and 9.00×10⁻⁷ Ωm or less.

The method for laminating a carbon material layer is not particularly limited as long as the carbon material layer is laminated on the base material. However, in a case where the carbon material layer is thin, chemical vapor deposition (CVD) method is employed. Examples of CVD method include thermal CVD method and microwave surface-wave plasma CVD method. The microwave surface-wave plasma CVD method enables formation of a large-area carbon material layer at a low temperature and with high efficiency.

In a case where the carbon material layer is thick to some extent (for example, when more than three graphene monolayers are laminated), a transfer method is employed as an example of the method for laminating a carbon material layer. In the transfer method, a previously prepared carbon material layer is transferred to the base material.

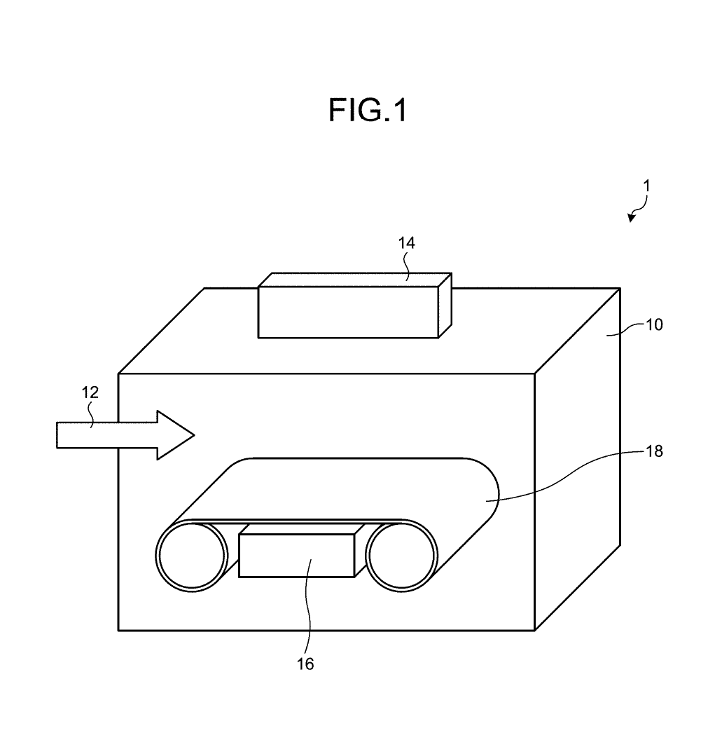

The lamination of a carbon material layer by the microwave surface-wave plasma CVD method, for example, will hereinafter be described. FIG. 1 illustrates an example of a CVD apparatus used in microwave surface-wave plasma CVD method.

A CVD apparatus 1 includes at least a discharge chamber 10, a gas supply unit 12, a plasma generation unit 14, and a heater 16.

First, a roll 18 made of a metallic material that is to be included in a base material of an electrical contact material is disposed on a specimen stage (not illustrated) in the discharge chamber 10, and the pressure of the discharge chamber 10 is set to 10⁻⁴ Pa or more and 10⁻² Pa or less. Subsequently, a mixed gas containing methane gas as a source gas, argon gas as inert gas, and hydrogen gas as an additive gas is supplied from the gas supply unit 12 to the discharge chamber 10, and the pressure of the discharge chamber 10 is set to 10 Pa or less, preferably, 2 Pa or more and 5 Pa or less. Simultaneously with the supply of the mixed gas, microwave (electric power: for example, 1 kW or more and 5 kW or less) is supplied to the plasma generation unit 14 to generate surface-wave plasma inside the discharge chamber 10. Accordingly, graphene is deposited on the roll 18. In other words, a layer including a graphene monolayer or a graphene laminate, that is, the carbon material, is laminated on the roll 18.

In the lamination of a carbon material layer, in order to keep the roll 18 on the specimen stage for, for example, 30 seconds or more and 180 seconds or less, that is, in order to invest, for example, 30 seconds or more and 180 seconds or less in deposition time, a carbon material layer is laminated while the roll 18 is reeled.

In the lamination of a carbon material layer, the heater 16 is used to control the temperature of the roll 18 on the specimen stage to, for example, 300° C. or more and 400° C. or less. The temperature of the roll 18 was measured with a thermocouple previously provided in the discharge chamber 10.

Furthermore, in the lamination of a carbon material layer, a supplied gas may be any but the mixed gas.

The supplied gas may contain at least a source gas that contains carbon or may contain only the source gas. In addition to methane gas, examples of the source gas include ethylene gas, acetylene gas, ethanol gas, acetone gas, and methanol gas. The source gas may be used individually, or two or more kinds of source gases may be used in combination.

The supplied gas may be a mixed gas that contains an inert gas, as described above. In addition to argon gas, examples of the inert gas include helium gas and neon gas. The inert gas may be used individually, or two or more kinds of inert gases may be used in combination. Inert gases have functions of stabilizing and making plasma uniform at low temperatures.

Furthermore, the supplied gas may be a mixed gas that contains an additive gas such as hydrogen gas, as described above. Additive gases are considered to have a function of homogenizing the carbon material layer.

In the microwave surface-wave plasma CVD method, the metallic material which is to be contained in the base material of the electrical contact material may have a shape other than the roll 18. For example, the metallic material may be a plate which is not rolled. In other words, the lamination of a carbon material layer may be carried out continuous, as described above, or in batches.

In a case where the electrical contact material includes an intermediate layer, in the lamination of a carbon material layer, a base material on which an intermediate layer is provided in advance may be used instead of the base material.

In addition, the preparation of an electrical contact material may involve pretreatment of the base material, and in the lamination of a carbon material layer, the layer that contains the carbon material may be formed on the pretreated base material. Specifically, the pretreatment is a step to clean a surface of the roll 18 with, for example, pretreatment gas plasma containing an inert gas such as argon and hydrogen gas. Accordingly, it is possible to laminate a carbon material layer that has excellent conductivity and contact reliability when forming a carbon material layer as an electrical contact.

The carbon material layer is formed on the base material in this manner, and the thickness of the carbon material layer and the number of graphene layers are adjusted by appropriately setting, for example, the deposition time, the temperature of the base material, the composition or amount of the supplied gas, and the type of the base material. For example, in a case where methane gas is used as a source gas, due to a difference in solid solubility of carbon with respect to the substrate, a graphene monolayer is formed when using a copper base material, and a graphene laminate is formed when using a nickel base material.

Note that a device such as the electrical contact and the connector according to the present invention may be produced by appropriately processing the electrical contact material.

### EXAMPLES

### Production Example 1 Production of Electrical Contact Material

Using the CVD apparatus 1 illustrated in FIG. 1, a layer including a graphene monolayer was laminated on a copper foil roll by microwave surface-wave plasma CVD method.

First, the copper foil roll 18 was placed on the specimen stage of the discharge chamber 10 and was pretreated. Specifically, a surface of the copper foil on the specimen stage was cleaned with pretreatment gas plasma of argon gas and hydrogen gas for 20 minutes at 5 Pa.

The next step was to laminate a carbon material layer. Specifically, the pressure of the discharge chamber 10 was set to 10⁻³ Pa. A mixed gas containing methane gas, argon gas, and hydrogen gas (methane gas/argon gas/hydrogen gas=30/20/10 SCCM (standard: 0° C./ atm, cc/min)) was then supplied from the gas supply unit 12 to the discharge chamber 10, and the pressure of the discharge chamber 10 was set to 3 Pa. Simultaneously with the supply of the mixed gas, microwave (electric power: 4.5 kW) was supplied to the plasma generation unit 14 to generate surface-wave plasma. Accordingly, graphene was deposited on the copper foil roll 18, and a layer including a graphene monolayer was laminated thereon. At the time of deposition, the temperature of the copper foil on the specimen stage was controlled by the heater 16. The temperature of the copper foil was measured with the thermocouple previously provided in the discharge chamber 10.

In the lamination of a carbon material layer, after the graphene was deposited for a certain period of time, the copper foil roll 18 was reeled so that a copper foil on which a carbon material layer is not laminated was placed on the specimen stage.

In addition, the copper foil newly placed on the specimen stage was pretreated, and a carbon material layer was laminated thereon. The pretreatment and the lamination and reeling of a carbon material layer were repeated to obtain the copper foil roll 18 with carbon material layers laminated thereon.

### Reference Production Example 1 Graphite

A graphene laminate (graphite) having a thickness of 1.0 mm was prepared.

### Comparative Production Example 1

Prepared was a copper foil roll subjected only to pretreatment and not to the lamination of a carbon material layer described in Production Example 1.

### Evaluation

### Optical Microscopic Observation

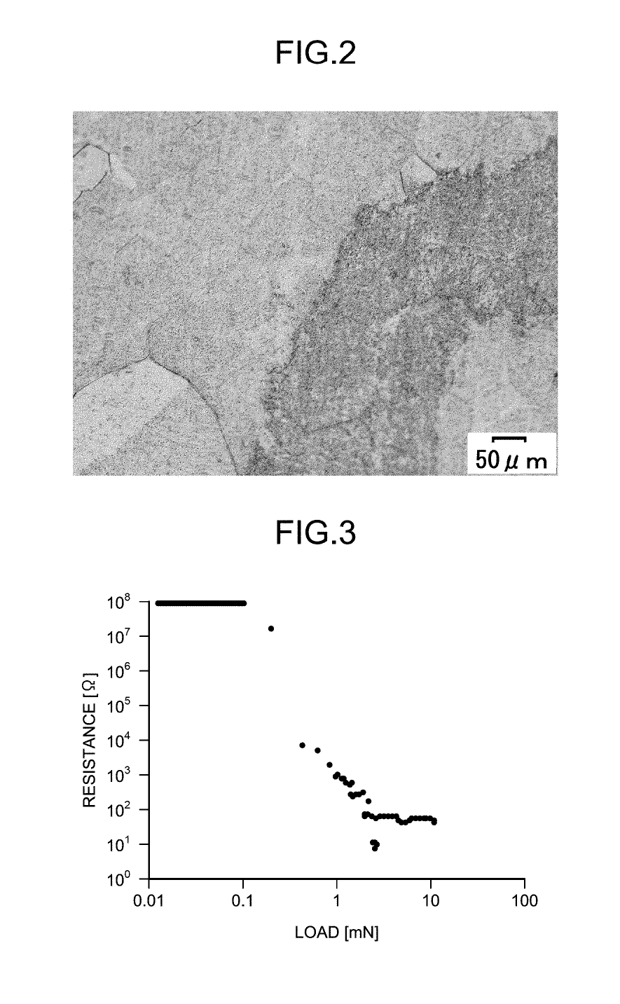

In regard to the electrical contact material of Production Example 1 and the copper foil of Comparative Production Example 1, an optical microscopic image was obtained. Specifically, the electrical contact material and the copper foil were observed at 10- to 100-fold magnification. FIGS. 2 and 5 illustrate the obtained images of the electrical contact material and the copper foil, respectively.

### Thickness of Carbon Material Layer and identification of Carbon Material

In regard to the electrical contact material of Production Example 1, the thickness of the carbon material layer was measured by an atomic force microscope (AFM). In the electrical contact material of Production Example 1, the thickness of the carbon material layer was 0.335 nm.

In regard to the electrical contact material of Production Example 1, a Raman spectroscopy spectrum was obtained using a Raman spectrometer (XploRa, available from Horiba, Ltd., excitation wavelength: 638 nm, beam spot size: 1 μm). Since a G band (around 1585 cm⁻¹) and a 2D band (around 2700 cm⁻¹) were observed, the carbon material layer of Production Example 1 was identified as a layer including a graphene monolayer.

From the position and intensity of the 2D band, and from an intensity ratio of the 2D band to the G band, it was determined that a graphene monolayer was formed in Production Example 1.

The electrical contact material of Production Example 1 was determined to include a graphene monolayer. Accordingly, the carbon material layer in the electrical contact material is considered to have a thickness of 0.335 nm. As described above, in regard to the carbon material layer in the electrical contact material of Production Example 1 estimated from the Raman spectroscopy spectrum, the thickness was equal to the measurement result obtained by the atomic force microscope (AFM).

### Measurement of Load Resistance

First, in regard to the electrical contact material of Production Example 1 and the copper foil of Comparative Production Example 1, a load resistance was measured. In a device used in this measurement, a nanoindentation manipulator with an indentation length adjustable at the nanometer scale was incorporated in a specimen chamber of a field emission scanning electron microscope (Fe-SEM) (S-4300, available from Hitachi High-Technologies Corporation).

Specifically, a specimen (5 mm square) was set in the specimen chamber, and an indentation test was performed on the specimen, using a tungsten probe with a tip radius of curvature processed to 5 μm. While observing the specimen with a scanning electron microscope (acceleration voltage: 5 kV, detector: secondary electron detector), an indentation depth of the tungsten probe, a contact load, and an electrical contact resistance were measured simultaneously. The tungsten probe was pushed into the specimen by 100 nm. The contact load was obtained by a strain gauge, and the electrical contact resistance was obtained by four-terminal sensing (resistance meter 3541 available from Hioki E. E. Corporation).

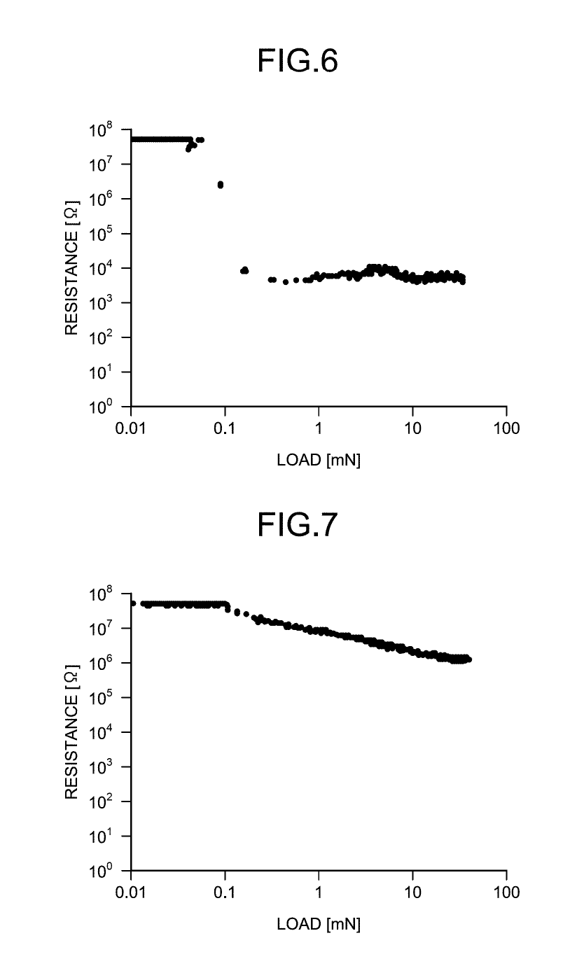

FIGS. 3 and 6 illustrate the measurement results on the load resistance of the electrical contact material and the copper foil, respectively.

Next, an oxidation acceleration test was performed on the electrical contact material of Production Example 1 and the copper foil of Comparative Production Example 1. Specifically, under atmospheric pressure, the specimen was exposed, for 16 hours, to air heated to 180° C.

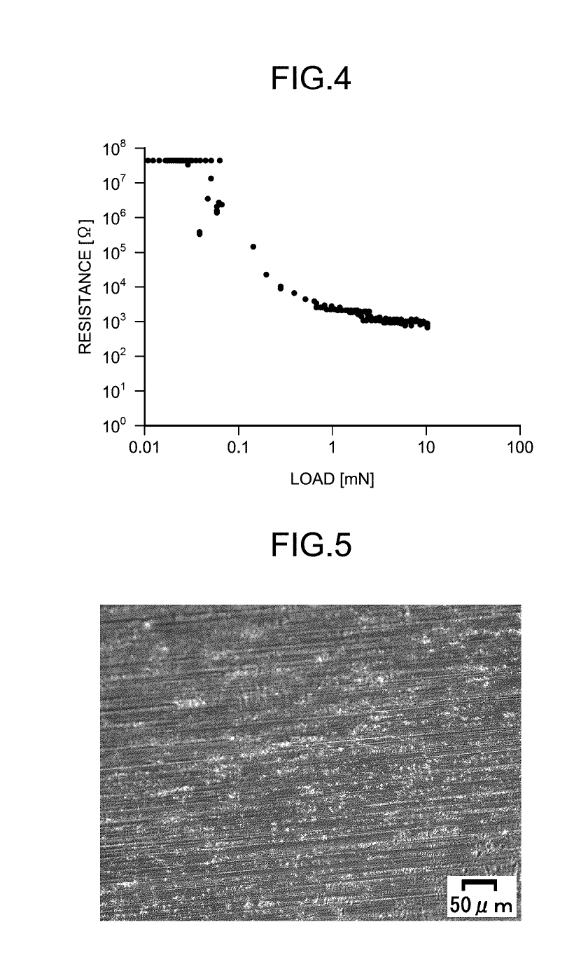

In regard to the specimen after the oxidation acceleration test, the measurement of load resistance as described above was carried out again. FIGS. 4 and 7 illustrate the measurement results on the load resistance of the electrical contact material and the copper foil, respectively.

As illustrated in FIG. 3 and FIG. 6, when a load is applied to the electrical contact material of Production Example 1 and the copper foil of Comparative Production Example 1 to some extent, the resistance of the electrical contact material and that of the copper foil greatly decrease. From these results, similarly to the copper foil, the electrical contact material of Production Example 1 is considered to have excellent conductivity when used as an electrical contact.

As illustrated in FIG. 7, in the copper foil of Comparative Production Example 1 after the oxidation acceleration test, the reduction of the resistance becomes small when a load is applied to the copper foil. possible reason is that the oxidation acceleration test causes formation of an oxide layer on a surface of the copper foil and leads to hindrance of conduction.

On the other hand, as illustrated in FIG. 4, in the electrical contact material of Production Example 1 after the oxidation acceleration test, the resistance greatly decreases when a load is applied to the electrical contact material to some extent. Comparison between FIG. 4 and FIG. 3 show that the reduction of the resistance changes a little. This result shows that the carbon material layer prevents generation of an oxide film. Accordingly, the electrical contact material of Production Example 1 is considered to have excellent conductivity even after the oxidation acceleration test.

### Determination of Conductivity

In regard to the graphene laminate of Reference Production Example 1, an electrical resistance was measured by two-terminal sensing to determine conductivity. The electric resistance was 0.1Ω or less. This result shows that the graphene laminate has conductivity. Accordingly, it is considered that the electrical contact including the graphene laminate of Reference Production Example 1 as a carbon material layer also prevents generation of an oxide film and that the electrical contact has excellent conductivity and contact reliability.

### Production Example 2 Production of Electrical Contact Material

A layer including a graphene monolayer was laminated on a copper substrate (10 mm in width, 10 mm in length, 1 mm in thickness) by thermal CVD using a heater.

### Production Example 3Production of Electrical Contact Material

A layer including a graphene laminate was laminated on a nickel substrate (10 mm in width, 10 mm in length, 1 mm in thickness) by thermal CVD using a heater.

### Evaluation

### External Observation and Optical Microscopic Observation

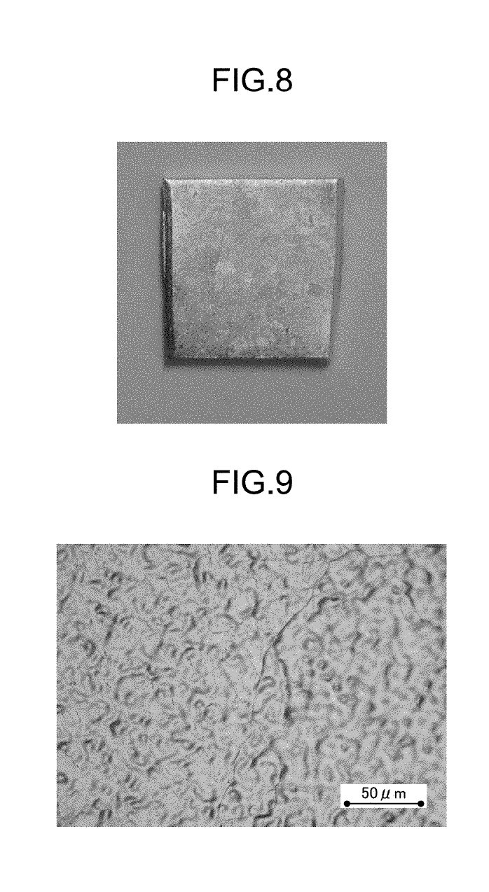

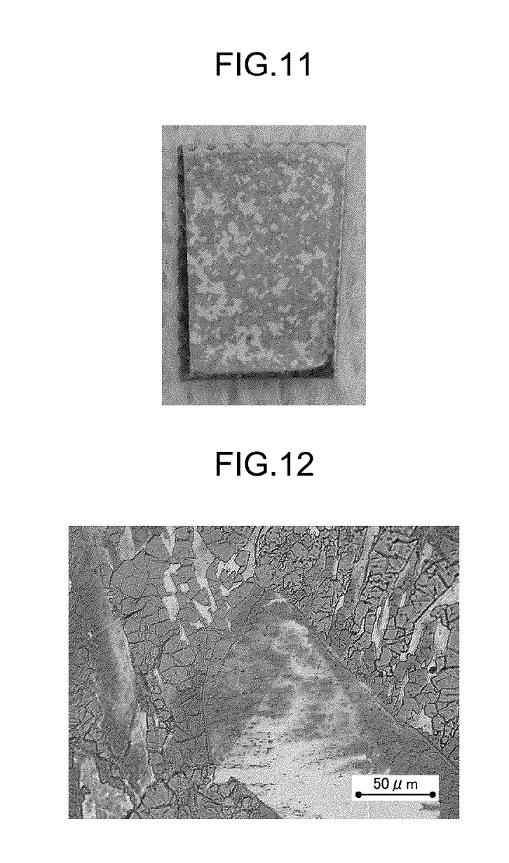

The external appearances of the electrical contact materials of Production Example 2 and Production Example 3 were observed. FIGS. 8 and 11 illustrate the obtained external appearances of the electrical contact materials of Production Example 2 and Production Example 3, respectively. In regard to the electrical contact materials of Production Example 2 and Production Example 3, an optical microscopic image was obtained. Specifically, the electrical contact materials were observed at 500-fold magnification. FIGS. 9 and 12 illustrate the obtained images of the electrical contact materials of Production Example 2 and Production Example 3, respectively.

### Identification of Carbon Material

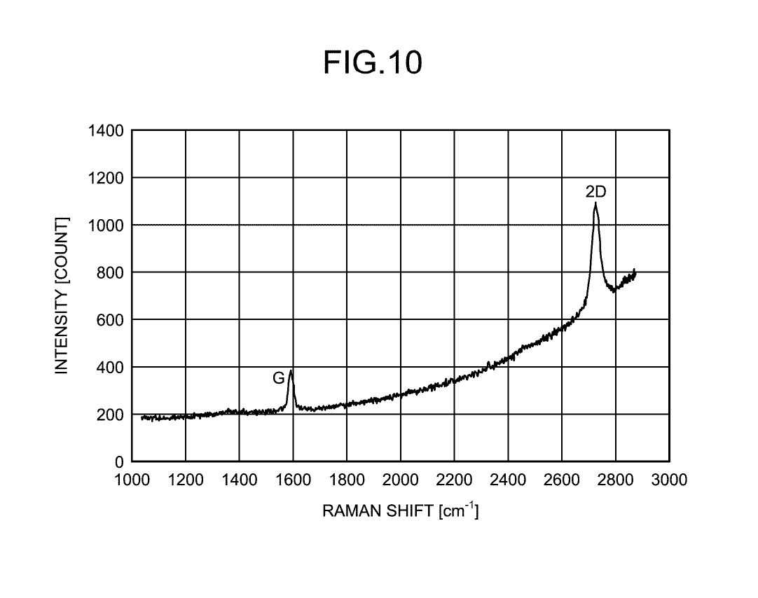

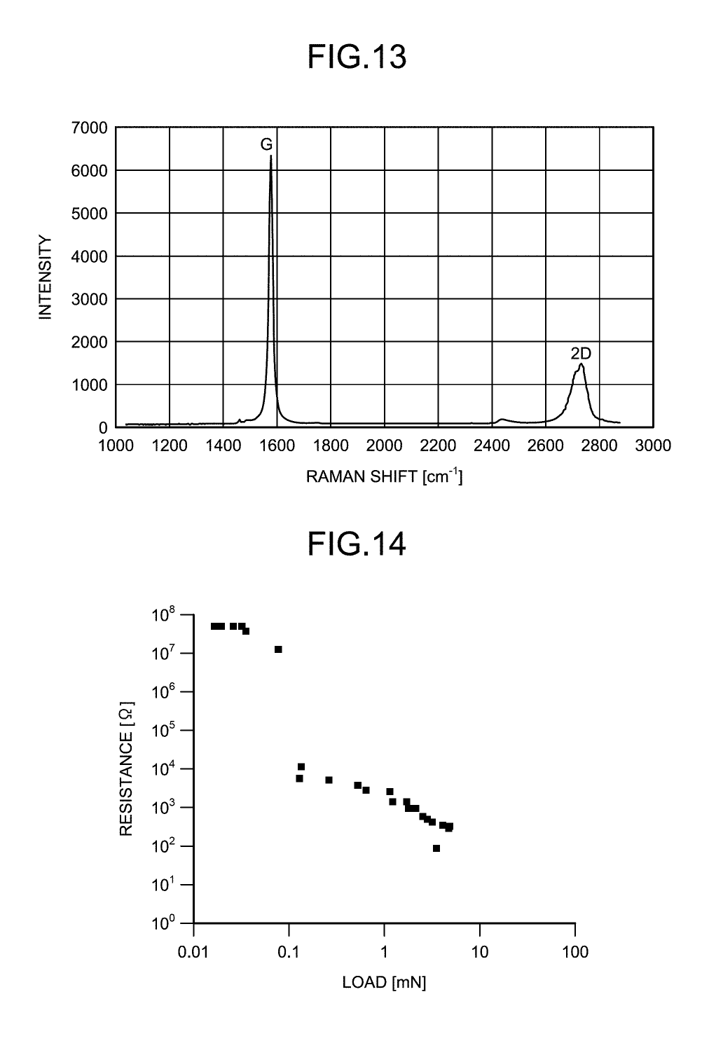

In regard to the electrical contact materials of Production Example 2 and Production Example 3, a Raman spectroscopy spectrum was obtained using a Raman spectrometer (LabRAN HR, available from Horiba, Ltd., excitation wavelength: 488 nm, beam spot size: 1 μm). FIG. 10 and FIG. 13 illustrate the obtained Raman spectroscopy spectra in regard to the electrical contact materials of Production Example 2 and Production Example 3, respectively. In the electrical contact material of Production Example 1, when the peak value of the 2D band (1585 cm⁻¹) and the peak value of the G band (2700 cm⁻¹) were compared, the peak value of the 2D band>the peak value of the G band. From this result, the electrical contact material of Production Example 1 was determined to include a graphene monolayer. In the electrical contact material of Production Example 3, when the peak value of the 2D band and the peak value of the G band were compared, the peak value of the 2D band<the peak value of the G band. From this result, the electrical contact material was determined to include a graphene laminate. Herein, the peak value indicates the peak intensity after background correction. Even when the Raman spectrometer used for the measurement of the electrical contact material of Production Example 1 is used in the measurement of the electrical contact materials of Production Examples 2 and 3, it is considered that similar results as the Raman spectroscopy spectra illustrated in FIGS. 10 and 13 are obtained. Furthermore, even when the Raman spectrometer used for the measurement of the electrical contact materials of Production Examples 2 and 3 is used in the measurement of the electrical contact material of Production Example 1, it is considered that the carbon material layer is identified as a layer including a graphene monolayer.

In the electrical contact material of Production Example 3, the thickness of the carbon material layer was considered to be about 100 nm from the result of cross-section measurement by TEM. From this result, the electrical contact material was determined to include about three hundred graphene monolayers laminated therein.

### Measurement of Load Resistance

In regard to the electrical contact material of Production Example 3, a load resistance was measured as in Production Example 1. FIG. 14 illustrates the measurement results on the load resistance. When a load is applied to the nickel substrate of Production Example 3 to some extent, the resistance greatly decreases. From this result, similarly to the copper foil of Comparative Production Example 1, the electrical contact material of Production Example 3 is considered to have excellent conductivity when used as an electrical contact.

In a case of performing the oxidation acceleration test, when a load is applied to the electrical contact material of Production Example 3 to some extent, the resistance is considered to decrease greatly as in Production Example 1. In other words, similarly to the electrical contact material of Production Example 1, the carbon material layer in the electrical contact material of Production Example 3 prevents generation of an oxide film, which indicates that the electrical contact material of Production Example 3 have excellent conductivity even after the oxidation acceleration test.

An electrical contact according to the embodiments has high contact reliability and enables reduction in production cost.

Although the invention has been described with respect to specific embodiments for a complete and clear disclosure, the appended claims are not to be thus limited but are to be construed as embodying modifications and alternative constructions that may occur to one skilled in the art that fairly fall within the basic teaching herein set forth.

What is claimed is:

1. A method for producing an electrical contact comprising:
a step of preparing an electrical contact material including a layer that contains a carbon material on a base material that contains a metallic material having resistivity of 1.59×10⁻⁸ Ωm or more and 9.00×10⁻⁷ Ωm or less; and
a step of processing the electrical contact material obtained to produce an electrical contact, wherein
the carbon material is a graphene monolayer or a graphene laminate in which a plurality of the graphene monolayers is laminated,
the step of preparing an electrical contact material includes a step of laminating a carbon material layer in which the layer that contains the carbon material is laminated on the base material by microwave surface-wave plasma CVD method or thermal CVD method, and
the step of laminating a carbon material layer includes supplying a mixed gas including a source gas that contains carbon and hydrogen gas.

2. The method for producing an electrical contact according to claim 1, wherein
the step of preparing an electrical contact material further comprises a step of conducting a pretreatment in which a surface of the base material is cleaned with pretreatment gas plasma containing an inert gas and hydrogen gas, and
the step of laminating a carbon material layer is a step of laminating the layer that contains the carbon material on the base material pretreated by the step of conducting a pretreatment.

3. The method for producing an electrical contact according to claim 1, wherein
the step of laminating a carbon material layer includes heating the base material and supplying the mixed gas.

4. The method for producing an electrical contact according to claim 3, wherein
the step of laminating a carbon material layer includes heating the base material at a temperature of 300° C. to 400° C. and supplying the mixed gas.
